(19) United States
(12) Patent Application Publication
(10) Pub. No.: US 2015/0198888 A1
(43) Pub. Date: Jul. 16, 2015

(54) METHOD FOR MANUFACTURING SUBSTRATE FOR PACKAGE

(71) Applicant: SAMSUNG ELECTRO-MECHANICS CO., LTD., Gyeonggi-Do (KR)

(72) Inventors: Chang Bo LEE, Suwon-si (KR); Dae Jo HONG, Suwon-si (KR); Myeong Ho HONG, Changwon-si (KR)

(73) Assignee: SAMSUNG ELECTRO-MECHANICS CO., LTD., Gyeonggi-Do (KR)

(21) Appl. No.: 14/594,462

(22) Filed: Jan. 12, 2015

(30) Foreign Application Priority Data
Jan. 13, 2014 (KR) 10-2014-0003986

(51) Int. Cl. G03F 7/20; G03F 7/30

(52) U.S. Cl. CPC G03F 7/2024; G03F 7/30; G03F 7/2002

(57) ABSTRACT

Embodiments of the invention provide a method for manufacturing a substrate for a package, in which the method includes forming a solder resist layer on an uncoated substrate having electrode pads formed thereon to cover the electrode pads, and exposing some regions by dividing the solder resist layer into regions including a first region covering some or all of the electrode pads and a second region formed out of the first region and exposing some of the regions. The method further includes developing the solder resist layer including an exposed region and an unexposed region with high energy light, so that a remaining height of the first region is lower than that of the second region and at least upper surfaces of the electrode pads in the first region are exposed.

### CROSS REFERENCE TO RELATED APPLICATION

This application claims the benefit of and priority under 35 U.S.C. §119 to Korean Patent Application No. KR 10-2014-0003986, entitled “METHOD FOR MANUFACTURING SUBSTRATE FOR PACKAGE,” filed on Jan. 13, 2014, which is hereby incorporated by reference in its entirety into this application.

### BACKGROUND

1. Field of the Invention

Embodiments of the present invention relates to a method for manufacturing a substrate for a package. More particularly, embodiments of the present invention relate to a method for manufacturing a substrate for a package without using a plasma etching, thinness chemicals, or a developing solution.

2. Description of the Related Art

In a solder resist (SR) process upon manufacturing a printed circuit board (PCB), opening the solder resist (SR) is a task necessary to secure a channel which is electrically connected to a chip which is to be packaged. A three-dimensional (3D) package has been recently spotlighted and a multilayer SR is required to satisfy a corresponding technical requirement. Among others, the solder resist is formed so that a copper (Cu) pattern or a copper (Cu) pad is exposed. In order to implement this, a method using a buffing, a method using a plasma etching, a method using thinness chemicals, a method using a general developing chemicals, and the like have been known. Here, the buffing method or the plasma etching method is a method in which the SR is first cured and is then formed to have a height below a Cu height by a physical or physicochemical method, and the method using the thinness chemicals or the method using the developing chemicals is a chemical method in which the SR is formed to have the height below the Cu height by using the thinness chemicals for an non-exposed portion (non-cured portion) of the SR or adjusting a concentration of the existing developing solution or a developing time. Since the method using the thinness chemicals or the method using the developing chemical has a simple process and does not use physical hitting force, it has a low quality risk compared to the buffing or plasma etching method. However, the thinness chemicals has a limitation in using for various SRs and the method using the existing developing chemicals has a limitation in adjusting a thickness according to non-uniform dissolution of the SR.

Korean Patent Publication No. KR 10-1084811 (registered Nov. 11, 2011), and Korean Patent Publication No. KR 10-2009-0006787 (published on Jan. 15, 2009).

### SUMMARY

Accordingly, embodiments of the invention have been made to provide a method for manufacturing a substrate for a package by selectively developing exposed and non-exposed portion using high energy light.

According to at least one embodiment, there is provided a method for manufacturing a substrate for a package, the method including forming a solder resist layer on an uncoated substrate having electrode pads formed thereon to cover the electrode pads, exposing some regions by dividing the solder resist layer into regions including a first region covering some or all of the electrode pads and a second region formed out of the first region and exposing some of the regions, and developing the solder resist layer including an exposed region and an unexposed region with high energy light so that a remaining height of the first region is lower than that of the second region and at least upper surfaces of the electrode pads in the first region are exposed.

According to at least one embodiment, in the developing of the solder resist layer with the high energy light, a developing depth of the first region is formed to be deeper than that of the second region according to a difference between internal bonding strengths of the solder resist layer in the exposed region and the unexposed region.

According to at least one embodiment, in the exposing of some regions, the region(s) other than the first region of the solder resist layer of a negative type is exposed and photo-cured by light of a photo-cure reaction wavelength band, and in the developing of the solder resist layer with the high energy light, the solder resist layer is developed by the high energy light out of the photo-cure reaction wavelength band.

According to at least one embodiment, in the exposing of some regions, the first region of the solder resist layer of a positive type is exposed.

According to at least one embodiment, in the developing of the solder resist layer with the high energy light, ultraviolet light or infrared light is used as the high energy light.

According to at least one embodiment, in the developing of the solder resist layer with the high energy light, a height of the solder resist layer of the first region is developed to be lower than the upper surfaces of the electrode pads in the first region.

According to at least one embodiment, in the exposing of some regions, the second region is formed outside the first region.

According to at least one embodiment, the method further includes post-curing the solder resist layer developed by the high energy light.

According to at least one embodiment, the first region and the second region of the solder resist layer, which is post-cured, have surface characteristics formed to be different from each other.

According to at least one embodiment, the first region of the solder resist layer, which is post-cured, has surface roughness formed to be larger than that of the second region.

According to at least one embodiment, in the exposing of some regions, the solder resist layer is divided into the first region, the second region, and a third region formed outside the first and second regions and some regions are sequentially exposed with different exposing energy, so that a first exposed region, a second exposed region, and the unexposed region are formed. In the developing of the solder resist layer with the high energy light, the first and second exposed regions and the unexposed region are developed by using the high energy light and are developed, so that the remaining height of the first region is lower than that of the second region, at least the upper surfaces of the electrode pads in the first region are exposed, and a remaining height of the second region is lower than that of the third region.

According to at least one embodiment, the first region of the solder resist layer, which is post-cured, has surface roughness formed to be larger than those of the second region and the third region.

According to at least one embodiment, in the exposing of some regions, the second region is formed outside the first region, and the method further includes forming a third region protruded from an edge region of the second region by applying, partially exposing and developing an additional solder resist on the solder resist layer, which is post-cured

According to at least one embodiment, a value of the surface roughness of the solder resist layer cured after the forming of the third region is formed, so that the surface roughness of the first region is larger than that of the second and third regions.

According to at least one embodiment, in the developing of the solder resist layer with the high energy light, the solder resist layer is photo-developed by using an excimer ultraviolet (UV).

According to at least one embodiment, the excimer UV has a wavelength of 300 nm or less.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIGS. 1A to 1D are views schematically showing a cross-section for each step in a method for manufacturing a substrate for a package according to an embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

Hereinafter, various embodiments of the present invention will be described in detail with reference to the accompanying drawings.

A method for manufacturing a substrate for a package according to at least one embodiment of the invention will be described in detail with reference to the accompanying drawings. In the specification, the same reference numerals will be used in order to describe the same components throughout the accompanying drawings.

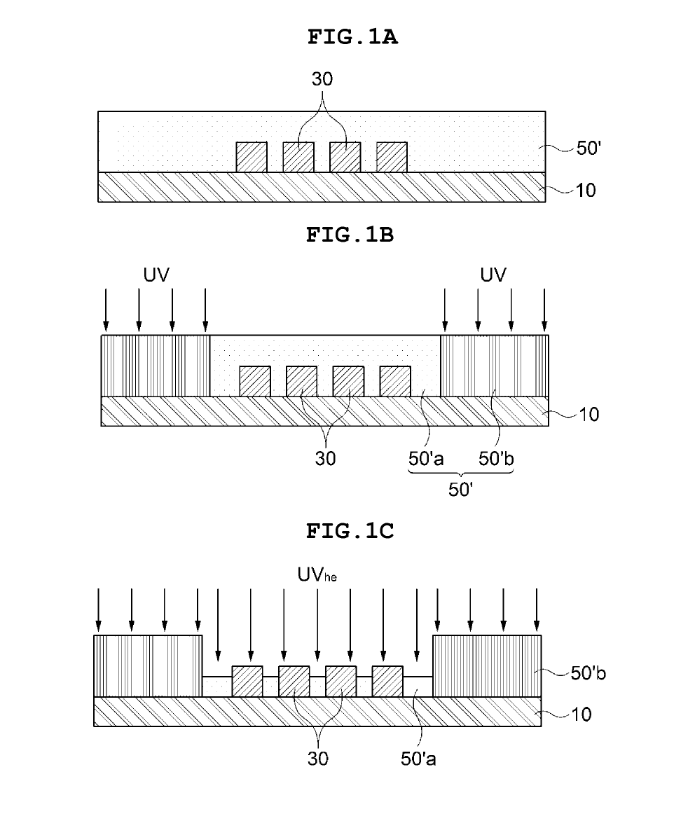

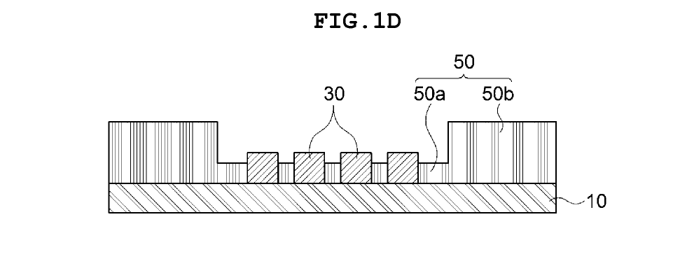

FIGS. 1A to 1D are views schematically showing a cross-section for each step in a method for manufacturing a substrate for a package according to an embodiment of the invention.

Referring to FIGS. 1A to 1C, a method for manufacturing a substrate for a package, according to at least one embodiment, is configured to include forming a solder resist layer (see FIG. 1A), exposing some regions (see FIG. 1B), and developing the solder resist layer with high energy light (see FIG. 1C). In addition, referring to FIG. 1D, the method for manufacturing the substrate for the package, according to at least one embodiment, further includes post-curing the developed solder resist layer (see FIG. 1D).

Referring to FIG. 1A, in the forming of the solder resist layer, a solder resist layer 50′ is formed on an uncoated substrate 10 having electrode pads 30 formed thereon to cover the electrode pads 30. According to at least one embodiment, the uncoated substrate 10 refers to a substrate before the solder resist layer 50′ is not coated.

Next, according to at least one embodiment, referring to FIG. 1B, in the exposing of some regions, the solder resist layer 50′ is exposed. In FIG. 1B, reference numeral 50′b indicates a region in which the solder resist layer 50′ formed by the forming of the solder resist layer of FIG. 1A is exposed, for example, a second region 50′b. First, the solder resist layer 50′ is divided into regions and some regions among the divided regions are exposed. The regions of the solder resist layer 50′ include a first region 50′a covering some or all of the electrode pads 30 and a second region 50′b formed out of the first region 50′a. According to at least one embodiment, some regions of the first region 50′a and the second region 50′b are exposed. Although not shown, some regions are exposed by using a photomask. For example, in a case of a negative method, the second region 50′b, which is not removed by a later developing process, is exposed. For example, the exposure in the exposing of some regions is performed by using light in a photoreaction wavelength band, for example, ultraviolet light, visible light and/or infrared light. In this case, the photoreaction wavelength band is determined depending on a photoinitiator included in the solder resist (SR).

For example, according to at least one embodiment, in the exposing of some regions, the regions of the solder resist layer 50′ are divided, so that the second region 50′b is formed outside the first region 50′a.

For example, according to at least one embodiment, in the exposing of some regions, the region(s) other than the first region 50′a of the solder resist layer 50′ of the negative type are exposed and photo-cured with the light in the photo-cure reaction wavelength band. For example, the exposure in the exposing of some regions is performed by using the light in the photo-cure reaction wavelength band, for example, ultraviolet light, visible light and/or infrared light. Thus, the exposed region is photo-cured by using the ultraviolet light, the visible light and/or the infrared light in the reaction wavelength band of the photoinitiator included in the solder resist (SR). For example, the exposed region is photo-cured by using a wideband ramp on the basis of three wavelengths of 365 nm, 405 nm, and 436 nm as a light source.

In a case of a negative solder resist (SR), when the light in the photo-cure reaction wavelength band is irradiated thereto, the negative solder resist is photo-cured, such that a crosslink between a single molecule and a high molecule of the solder resist (SR) is performed. The crosslinked portion becomes the high molecular state in which the single molecule is little present by a chemical bond such as an intramolecular bonding, such as a covalent bonding, an ion bonding between elements, as non-limiting examples, and is maintained in an intermolecular bonding state between the single molecule and the high molecule of the unexposed region.

Alternatively, although not shown, according to at least one more embodiment of the invention, in the exposing of some regions, the first region of the solder resist layer of a positive type is exposed. In this case, the light of the wavelength band causing a positive photoreaction to be generated is irradiated to the first region to positively expose the first region. Here, unlike the negative solder resist, in a case of the positive solder resist, a degree of cross-link is not changed and a molecular composition of the solder resist is changed to a composition, which may be developed according to the light irradiation of the photoreaction wavelength band.

Next, according to at least one embodiment, referring to FIG. 1C, in the developing of the solder resist layer with the high energy light, the solder resist layer 50′ including the exposed region and the unexposed region is developed by using high energy light In this case, the solder resist layer 50′ is developed by the high energy light so that the remaining height of the first region 50′a is lower than that of the second region 50′b and at least upper surfaces of the electrode pads 30 in the first region 50′a are exposed. For example, the high energy light may be irradiated by adjusting the wavelength band, an exposure amount and/or an exposure time.

For example, in the developing of the solder resist layer with the high energy light, the ultraviolet light or the infrared light may be used as the high energy light. For example, the ultraviolet (UV) light is used as the high energy light. The wavelength band of the high energy light is determined in consideration of the photoreaction wavelength band of the light used in the exposing of some regions (see FIG. 1B). For example, when the high energy light having a short wavelength other than the photoreaction wavelength band is irradiated, this high energy light photo-decomposes or photo-develops the solder resist layer 50′ while bringing about a physicochemical change only in the vicinity of a surface of the solder resist layer 50′ due to bad transmittance into the solder resist layer 50′. For example, when the high energy light is irradiated to a cured region, an uncured region, or a semi-cured region of the solder resist layer 50′, more photo-decomposition reactions relatively occurs on a surface of the uncured or semi-cured region, rather than a surface of the cured region and the photo-decomposition reactions are successively performed, thereby making it possible to form a step between the first region 50′a and the second region 50′b.

For example, in the case in which the solder resist (SR) is negatively photoreacted, in the developing of the solder resist layer with the high energy light, the solder resist layer 50′ is developed by the high energy light other than the photo-cure reaction wavelength band. For example, the solder resist layer 50′ is developed by the high energy light having the wavelength band smaller than the photo-cure reaction wavelength band. For example, in the case in which the solder resist layer is exposed by the light having the wavelength band of 365 to 436 nm, for example, in the exposing of some regions (see FIG. 1B), the solder resist layer 50′ is developed by a high energy UV light having a wavelength band smaller than the wavelength band of 365 to 436 nm, for example, a wavelength band of 300 nm or less.

Alternatively, in the case in which the solder resist (SR) is positively photoreacted, in the developing of the solder resist layer with the high energy light, the solder resist layer 50′ is positively photo-decomposed or photo-developed by the high energy light other than the photoreaction wavelength band or the high energy light having a positive photoreaction wavelength band. In this case, the light is irradiated to only the positive exposed region having the changed molecular composition, for example, the surface of the first region 50′a by using the photomask (not shown), for example, such that the photo-decomposition may be performed.

Referring to FIG. 1C, according to at least one embodiment of the invention, in the developing of the solder resist layer with the high energy light, a developing depth of the first region 50′a is formed to be deeper than that of the second region 50′b according to a difference between internal bonding strengths of the solder resist layer 50′ in the exposed region and the unexposed region. According to at least one embodiment, the developing depth, which is formed by the photo-chemical decomposition, is selectively adjusted for each region by using the bonding strength difference of the exposed region and the unexposed region of the solder resist.

Typically, when the negative solder resist (SR) is exposed by for example, the ultraviolet, the photo-cure reaction occurs, such that an intermolecular crosslinking is performed and the chemical bond such as an intramolecular bonding, such as a covalent bonding, an ion bonding, as non-limiting examples, between the elements is performed in the crosslinked region. On the other hand, the single molecule and the high molecule, which are not crosslinked, form the intermolecular bonding with each other. Representative examples of the intramolecular bonding formed between the elements in the single molecule or the crosslinked high molecules includes the covalent bonding, for example, and representative examples of the intermolecular bonding include a van der Waals bonding, a hydrogen bonding, for example. Generally, it is known that the intramolecular bonding is very strong as compared to the intermolecular bonding. Thus, when energy is received from the outside, the decomposition reaction occurs relatively easier at the intermolecular bonding region than the intramolecular bonding region. An example of those described above includes a development reaction (decomposition) using a developing solution, a thinness chemicals, for example, according to the conventional art. For example, in a case of the negative type, since the unexposed region is not photo-cured and forms the intermolecular bonding between the molecules to thereby have bonding force weaker than the crosslinked region by the photo-cure, thereby being easily developed. Describing dissociation energy representing a bonding strength for each bonding form, for example, dissociation energy of the covalent bonding, which is the intramolecular bonding, is approximately 400 kcal/mol while dissociation energy of the hydrogen bonding, which is intermolecular bonding, is approximately 12 to 16 kcal/mol, dissociation energy of a dipole-diple bonding, which is intermolecular bonding, is approximately 0.5 to 2 kcal/mol, and dissociation energy of the van der Waals bonding, which is intermolecular bonding, is approximately below 1 kcal/mol. Therefore, the intermolecular bonding is easily dissociated as compared to the intramolecular bonding.

According to at least one embodiment, in the case of the positive solder resist (SR), in the developing of the solder resist layer with the high energy light, the high energy light of the photoreaction wavelength band is irradiated to only the positive photoreaction region having the changed molecular composition, thereby making it possible to allow the photo-decomposition reaction to occur.

In addition, referring to FIG. 1C, according to an exemplary embodiment of the present invention, in the developing of the solder resist layer with the high energy light, the solder resist layer 50′ is developed, so that the height of the solder resist layer 50′ of the first region 50′a is lower than an upper surface of the electrode pads 30 in the first region 50′a.

For example, according to at least one other exemplary embodiment, in the developing of the solder resist layer with the high energy light, the photo development is performed by using the ultraviolet (UV) light, for example, the excimer UV.

According to at least one embodiment, the excimer UV has a wavelength of 300 nm or less, for example.

Next, referring to FIG. 1D, the method for manufacturing the substrate for the package, according to at least one embodiment, further includes post-curing the developed solder resist layer. In this case, in the post-curing of the developed solder resist layer, the solder resist layer 50′a, which is developed by the high energy light, is post-cured. In FIG. 1D, reference numeral 50 shows the post-cured solder resist layer.

For example, in this case, surface characteristics of a first region 50a and a second region 50b of the post-cured solder resist layer 50 are formed to be different from each other. For example, surface roughness, surface energy, wettability, or a surface color (gloss) of the first region 50a and the second region 50b of the post-cured solder resist layer 50 are formed to be different from each other.

In FIG. 1D, according to at least one embodiment, the surface roughness of the first region 50a of the post-cured solder resist layer 50 is formed to be larger than that of the second region 50b. In FIG. 1D, reference numeral 50a shows the first region of the post-cured solder resist layer and reference numeral 50b shows the second region of the post-cured solder resist layer.

Although not shown, a method for manufacturing a substrate for a package, according to at least one other embodiment of the invention, will be described. According to at least one other embodiment of the invention, in the exposing of some regions (see FIG. 1B), although not shown, the solder resist layer 50′ is divided into regions including the first region 50′a, the second region 50′b, and a third region (not shown) formed outside the first and second regions 50′a and 50′b. In this case, some regions are sequentially exposed with different exposing energy, so that a first exposed region, a second exposed region, and an unexposed region are formed.

In addition although not directly shown, referring to FIG. 1C, in the developing of the solder resist layer with high energy light, the first and second exposed regions and the unexposed region are developed by using the high energy light In this case, the development is performed so that the remaining height of the first region 50′a is lower than that of the second region 50′b, at least upper surfaces of the electrode pads 30 in the first region 50′a are exposed, and the remaining height of the second region 50′b is lower than that of the third region.

For example, the surface roughness, surface energy or wettability of the region having the highest remaining height in the solder resist layer 50 is relatively lowest. In addition, according to at least one embodiment, the surface roughness, surface energy or wettability of the region having the lowest remaining height in the solder resist layer 50 is relatively highest.

For example, according to at least one embodiment of the invention, the surface roughness of the first region 50a of the post-cured solder resist layer 50 is formed to be larger than that of the second and third regions.

According to at least one embodiment, in addition, although not shown, the method for manufacturing the substrate for the package further includes forming a third region after the post-curing of the developed solder resist layer of FIG. 1D. According to at least one embodiment, first, in the exposing of some regions of FIG. 1B, the second region 50′b is formed outside the first region 50′a. In addition, in the forming of the third region after the post-curing of the developed solder resist layer of FIG. 1D, an additional solder resist layer is applied on the post-cured solder resist layer 50 and is partially exposed and developed, such that the third region (not shown) protruded from an edge region of the second region 50b is formed.

For example, a value of the surface roughness of the solder resist layer 50 cured after forming the third region (not shown) is larger than that of the second and third regions.

According to any one of the embodiments of the invention described above, the number of processes is decreased as compared to a buffing method in which the solder resist is firstly cured, the electrode pad is exposed by the buffing, and the solder resist is secondly then applied, exposed and developed, or a plasma method in which the solder resist is applied and the electrode pad is then exposed by the plasma etching according to the conventional art. In addition, according to at least one embodiment, lift risk in which the electrode pad is lift is decreased as compared to the buffing method according to the conventional art. In addition, since mechanical abrasion does not occur, scratches on the surface of the solder resist are decreased as compared to the buffing method according the conventional art. Further, the height of the solder resist is freely adjusted as compared to the buffing method according to the conventional art.

In addition, according to at least one embodiment, the thinness method exposing the electrode pad by using the thinness chemicals according to the related art needs the chemicals due to a wet process, while the present invention does not consume the chemicals.

In addition, according to at least one embodiment, distribution of the development depth is advantageously controlled as compared to the method for exposing the electrode pad by using the developing solution according to the conventional art.

Further, according to at least one other embodiment of the invention, packaging property becomes good by reforming the surface of the solder resist.

According to at least one embodiment of the invention, the substrate for the package is manufactured by selectively developing the exposed and non-exposed portion using high energy light. Therefore, the substrate for the package capable of exposing the electrode pad of some regions without using the plasma etching, the thinness chemicals, or the developing solution is manufactured.

In addition, according to at least one embodiment, the number of processes is be decreased compared to the buffing method or the plasma etching method according to the conventional art, the chemicals are not consumed unlike the thinness chemicals method according to the conventional art, and the distribution of the development depth are advantageously controlled as compared to the developing solution method according to the conventional art.

Further, according to at least one embodiment, packaging property becomes good by reforming the surface of the solder resist. For example, the effect of reforming the SR surface is provided as compared to the case according to the conventional art, such that the present invention is further useful when the complex object is required.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A method for manufacturing a substrate for a package, the method comprising:
forming a solder resist layer on an uncoated substrate comprising electrode pads formed thereon to cover the electrode pads;
exposing some regions by dividing the solder resist layer into regions comprising a first region covering some or all of the electrode pads and a second region formed out of the first region and exposing some of the regions; and
developing the solder resist layer including an exposed region and an unexposed region with high energy light, so that a remaining height of the first region is lower than that of the second region and at least upper surfaces of the electrode pads in the first region are exposed.

2. The method according to claim 1, wherein in the developing of the solder resist layer with the high energy light, a developing depth of the first region is formed to be deeper than that of the second region according to a difference between internal bonding strengths of the solder resist layer in the exposed region and the unexposed region.

3. The method according to claim 2, wherein in the exposing of some regions, the region(s) other than the first region of the solder resist layer of a negative type is exposed and photo-cured by light of a photo-cure reaction wavelength band, and
in the developing of the solder resist layer with the high energy light, the solder resist layer is developed by the high energy light out of the photo-cure reaction wavelength band.

4. The method according to claim 1, wherein in the exposing of some regions, the first region of the solder resist layer of a positive type is exposed.

5. The method according to claim 1, wherein in the developing of the solder resist layer with the high energy light, ultraviolet light or infrared light is used as the high energy light.

6. The method according to claim 1, wherein in the developing of the solder resist layer with the high energy light, a height of the solder resist layer of the first region is developed to be lower than the upper surfaces of the electrode pads in the first region.

7. The method according to claim 1, wherein in the exposing of some regions, the second region is formed outside the first region.

8. The method according to claim 1, further comprising:
post-curing the solder resist layer developed by the high energy light.

9. The method according to claim 3, further comprising:
post-curing the solder resist layer developed by the high energy light.

10. The method according to claim 8, wherein the first region and the second region of the solder resist layer, which is post-cured, have surface characteristics formed to be different from each other.

11. The method according to claim 9, wherein the first region and the second region of the solder resist layer, which is post-cured, have surface characteristics formed to be different from each other.

12. The method according to claim 10, wherein the first region of the solder resist layer, which is post-cured, has surface roughness formed to be larger than that of the second region.

13. The method according to claim 8, wherein in the exposing of some regions, the solder resist layer is divided into the first region, the second region, and a third region formed outside the first and second regions, and some regions are sequentially exposed with different exposing energy so that a first exposed region, a second exposed region, and the unexposed region are formed, and
in the developing of the solder resist layer with the high energy light, the first and second exposed regions and the unexposed region are developed by using the high energy light, so that the remaining height of the first region is lower than that of the second region, at least the upper surfaces of the electrode pads in the first region are exposed, and a remaining height of the second region is lower than that of the third region.

14. The method according to claim 9, wherein in the exposing of some regions, the solder resist layer is divided into the first region, the second region, and a third region formed outside the first and second regions, and some regions are sequentially exposed with different exposing energy so that a first exposed region, a second exposed region, and the unexposed region are formed, and
in the developing of the solder resist layer with the high energy light, the first and second exposed regions and the unexposed region are developed by using the high energy light, so that the remaining height of the first region is lower than that of the second region, at least the upper surfaces of the electrode pads in the first region are exposed, and a remaining height of the second region is lower than that of the third region.

15. The method according to claim 13, wherein the first region of the solder resist layer, which is post-cured, has surface roughness formed to be larger than those of the second region and the third region.

16. The method according to claim 8, wherein in the exposing of some regions, the second region is formed outside the first region, and
the method further comprising:
forming a third region protruded from an edge region of the second region by applying, partially exposing and developing an additional solder resist on the solder resist layer, which is post-cured.

17. The method according to claim 9, wherein in the exposing of some regions, the second region is formed outside the first region, and
the method further comprising:
forming a third region protruded from an edge region of the second region by applying, partially exposing and developing an additional solder resist on the solder resist layer, which is post-cured.

18. The method according to claim 16, wherein a value of the surface roughness of the solder resist layer cured after the forming of the third region is formed, so that the surface roughness of the first region is larger than that of the second and third regions.

19. The method according to claim 8, wherein in the developing of the solder resist layer with the high energy light, the solder resist layer is photo-developed by using an excimer ultraviolet (UV).

20. The method according to claim 19, wherein the excimer UV has a wavelength of 300 nm or less.
